(19) United States
(12) Patent Application Publication
(10) Pub. No.: US 2011/0080929 A1
(43) Pub. Date: Apr. 7, 2011

(54) SEMICONDUCTOR LASER DEVICE AND METHOD FOR FABRICATING THE SAME

(76) Inventors: Kazutoshi Onozawa, Osaka (JP); Satoshi Tamura, Osaka (JP)

(21) Appl. No.: 12/519,465

(22) PCT Filed: Jan. 8, 2009
(86) PCT No.: PCT/JP2009/000036

§ 371 Date: Jun. 16, 2009

(30) Foreign Application Priority Data
May 15, 2008 (JP) 2008-128306

(51) Int. Cl. H01S 5/323; H01S 5/22; H01L 21/30

(52) U.S. Cl. 372/45.01; 438/33; 257/E21.211

(57) ABSTRACT

A semiconductor laser device includes a substrate 11 having a (1-100) oriented principal surface, a semiconductor multilayer structure 12 formed on the substrate 11 and having a stripe-shaped optical waveguide, and a plurality of pyramidal protrusions 13 formed at least on a part of a light emitting facet of the substrate 11. The light emitting facet has a (000-1) plane orientation.

### TECHNICAL FIELD

The present invention relates to a semiconductor laser device and a method for fabricating the semiconductor laser device, and more particularly relates to a semiconductor laser device used as a light source in an optical disk device, etc. and a method for fabricating the semiconductor laser device.

### BACKGROUND ART

Semiconductor laser devices, which have excellent features, such as their compact size, low price, and high output, are particularly often used for recording and reproduction in optical disk devices. In recent years, blue-violet semiconductor laser devices that use group III-V nitride semiconductors, such as gallium nitride (GaN), and operate at a wavelength of about 405 nm have been vigorously developed for use in high-density optical disk devices, such as blue-ray optical disk devices, that record and reproduce high-definition clear video images.

In optical disk devices, noise in an optical pickup that performs recording and reproduction needs to be reduced. One of the causes of noise in the optical pickup is reflection of light off a facet of the semiconductor laser device. Light emitted from the semiconductor laser device in the optical pickup is reflected off the surface of the optical disc, and part of the reflected return laser light enters the semiconductor laser device. The light emitting facet of a semiconductor laser device is typically a minor surface formed by cleavage. Thus, the return laser light from the optical disc is reflected off the light emitting facet that is a minor surface, and reenters the optical system to become noise.

In particular, in a three-beam optical pickup, if sub beams for tracking, located on both sides of a main beam, are reflected off the light emitting facet of the semiconductor laser device, and re-form a spot on the optical disc, the tracking operation of the optical pickup will be greatly affected.

To prevent such noise and tracking errors caused by the reflection of return light, an approach has been tried in which a photoresist is applied to the light emitting facet of a semiconductor laser device, so that only the laser-light-emitting part is exposed to laser light, thereby becoming transparent; while the other part serves as an absorption layer, thereby preventing the reflection of return light off the light emitting facet (see, for example, Patent Document 1).

Another method has also been tried in which the light emitting facet of a semiconductor laser device is processed by dry etching so as to be a curved surface and thus scatter light, thereby preventing the reflection of return light off the light emitting facet (see, for example, Patent Document 2).

### Patent Document 1: Specification of Japanese Patent No. 2586536

### Patent Document 2: Japanese Laid-Open Publication No. 2004-349328

### DISCLOSURE OF THE INVENTION

### Problems that the Invention Intends to Solve

However, the conventional methods for preventing return light reflection have the following problems. First, the method of forming a light absorption layer by using a photoresist is difficult to apply to blue-violet semiconductor laser devices used in high-density optical disk devices. This is because blue-violet laser light of short wavelength degrades the resin, and thus, degrades the function of the light absorption layer.

Furthermore, the method of processing the light-emitting facet of a semiconductor laser device into a curved surface has a problem in that the processing is difficult, and stable fabrication of the product cannot be realized.

Therefore, it is an object of the present disclosure to solve the above-described problems, and to easily realize a semiconductor laser device capable of preventing return light reflection.

### Means for Solving the Problems

In order to achieve the object, a semiconductor laser device according to the present disclosure is configured so as to have pyramidal protrusions formed of specific crystal planes of a substrate at least on a part of a light emitting facet of the substrate.

Specifically, a semiconductor laser device according to the present disclosure is directed to an edge-emitting semiconductor laser device using a nitride semiconductor. The semiconductor laser device includes: a substrate made of a hexagonal nitride semiconductor and having a (1-100) oriented principal surface; a semiconductor multilayer structure formed on the substrate and having a stripe-shaped optical waveguide; and a plurality of pyramidal protrusions formed at least on a part of a region of a light emitting facet, the region being an area of the substrate exposed in the light emitting facet. The light emitting facet has a (000-1) plane orientation.

The semiconductor laser device according to the present disclosure includes the pyramidal protrusions formed at least on a part of the light emitting facet of the substrate. These pyramidal protrusions scatter return laser light entering the facet of the semiconductor laser device. Accordingly, noise, tracking errors, and the like caused by specular reflection of the return laser light off the facet are reduced.

In the semiconductor laser device according to the present disclosure, the pyramidal protrusions may be each shaped like a hexagonal pyramid, and may be formed of (1-102) oriented surfaces. In that case, the pyramidal protrusions are formed of crystal planes of the substrate, and thus do not degrade unlike a resist or the like. In addition, since it is sufficient to merely expose the crystal planes, the pyramidal protrusions are easily formed with a high degree of reproducibility.

In the semiconductor laser device according to the present disclosure, the semiconductor multilayer structure may include an n-type clad layer, an active layer, and a p-type clad layer sequentially stacked in this order; and the pyramidal protrusions may also be formed at least on a part of a region of the light emitting facet, the region being an area of the semiconductor multilayer structure exposed in the light emitting facet, the part being located under the active layer.

A method for fabricating a semiconductor laser device according to the present disclosure includes the steps of: (a) forming a semiconductor multilayer structure on a substrate having a (1-100) oriented principal surface, the semiconductor multilayer structure having a stripe-shaped optical waveguide; and (b) forming a recess having a (000-1) oriented inner wall surface by etching a side of the substrate located away from a side thereof where the semiconductor multilayer structure is formed, and forming pyramidal protrusions of (1-102) oriented surfaces on the inner wall surface.

In the semiconductor laser device fabrication method according to the present disclosure, the recess having a (000-1) oriented inner wall surface is formed by etching the backside of the substrate, and the pyramidal protrusions of (1-102) oriented surfaces are formed on the inner wall surface. Thus, the pyramidal protrusions are formed at least on a part of the light emitting facet of the substrate, and the semiconductor laser device capable of scattering return laser light is easily formed. Since it is sufficient to just expose the specific crystal planes of the substrate by etching, the pyramidal protrusions are easily formed with a high degree of reproducibility.

In the semiconductor laser device fabrication method according to the present disclosure, the etching is preferably wet etching.

In the semiconductor laser device fabrication method according to the present disclosure, the wet etching may be performed with an alkaline solution used as an etchant and with light applied, the light having such a wavelength that causes crystals of the nitride semiconductor to absorb the light.

In the semiconductor laser device fabrication method according to the present disclosure, the alkaline solution may be a potassium hydroxide solution.

The semiconductor laser device fabrication method according to the present disclosure may further include the step (c) of cleaving the semiconductor multilayer structure, thereby forming a cavity facet, after the step (b) has been performed. The recess may function as a guide groove in the cleavage.

The semiconductor laser device fabrication method according to the present disclosure may further include the step (d) of forming an n-side electrode on the side of the substrate located away from the semiconductor multilayer structure, before the step (b) is performed. In the step (b), the etching may be performed with the n-side electrode used as a mask.

### EFFECTS OF THE INVENTION

The semiconductor laser device and the fabrication method thereof according to the present disclosure easily realize a semiconductor laser device capable of preventing return light reflection.

### BRIEF DESCRIPTION OF DRAWINGS

FIG. 1 is a perspective view illustrating a semiconductor laser device according to an embodiment of the invention.

FIG. 2 is a cross-sectional view illustrating the semiconductor laser device according to the embodiment of the invention.

FIG. 3 is a cross-sectional view illustrating a process step in a method for fabricating the semiconductor laser device according to the embodiment of the invention.

FIG. 4 is a cross-sectional view illustrating a process step in the method for fabricating the semiconductor laser device according to the embodiment of the invention.

FIG. 5 is a cross-sectional view illustrating a process step in the method for fabricating the semiconductor laser device according to the embodiment of the invention.

FIG. 6 is a cross-sectional view illustrating a process step in the method for fabricating the semiconductor laser device according to the embodiment of the invention.

FIG. 7 is a cross-sectional view illustrating a process step in the method for fabricating the semiconductor laser device according to the embodiment of the invention.

FIG. 8 is a cross-sectional view illustrating a process step in the method for fabricating the semiconductor laser device according to the embodiment of the invention.

FIG. 9 is a cross-sectional view illustrating a process step in the method for fabricating the semiconductor laser device according to the embodiment of the invention.

FIGS. 10(a) and 10(b) illustrate the structure of pyramidal protrusions in the semiconductor laser device according to the embodiment of the invention. FIG. 10(a) is a plan view, and FIG. 10(b) is a side view.

FIGS. 11(a) and 11(b) are electron micrographs of the pyramidal protrusions in the semiconductor laser device according to the embodiment of the invention.

### EXPLANATION OF THE REFERENCE CHARACTERS

11 Substrate
12 Semiconductor multilayer structure
13 Pyramidal protrusions
20 Ridge stripe portion
21 N-type clad layer
22 N-type optical guide layer
23 Active Layer
24 P-type optical guide layer
25 OFS layer
26 P-type clad layer
27 P-type contact layer
31 Dielectric layer
32 P-side electrode
33 N-side electrode
40 Etching protective film
41 Recess
50 Alkaline solution

### DETAILED DESCRIPTION OF THE INVENTION

First, constituent material that is common to semiconductor laser devices according to an embodiment of the present disclosure will be discussed. In the following embodiment, semiconductor laser devices are formed by using group III-V nitride semiconductor material made of hexagonal (wurtzite) crystals having hexagonal symmetry. Group III-V nitride semiconductor material is material whose general formula is expressed as In_{1-x-y}Al_{y}GaₓN (0≦x, y≦1, and 0≦x+y≦1).

Hexagonal GaN crystals are polar crystals, and two kinds of surfaces are present in the same (0001) plane: a surface where atoms of gallium (Ga), a group III element, are arranged, and a surface where atoms of nitrogen (N), a group V element, are arranged. In this specification, a surface where atoms of a group III element, such as Ga, are arranged will be referred to as a (0001) plane, and a surface where atoms of N, a group V element, are arranged will be referred to as a (000-1) plane.

It should also be noted that a (0001) plane will be represented as a +c plane, and a (000-1) plane will be indicated as a −c plane. Likewise, a (1-100) plane will be represented as a +m plane, and a (−1100) plane will be indicated as a −m plane. Furthermore, it should be understood that planes simply expressed as “a c plane and the like” include a +c plane and a −c plane. In this specification, a (0001) plane, for example, not only means a (0001) plane, but includes a plane inclined in a range of from about −5° to about +5° with respect to the (0001) plane.

A light emitting facet means one of the two facets of a cavity that has a larger optical output power, and a rear facet means the opposing facet having a smaller optical output power than the light emitting facet.

### Embodiment

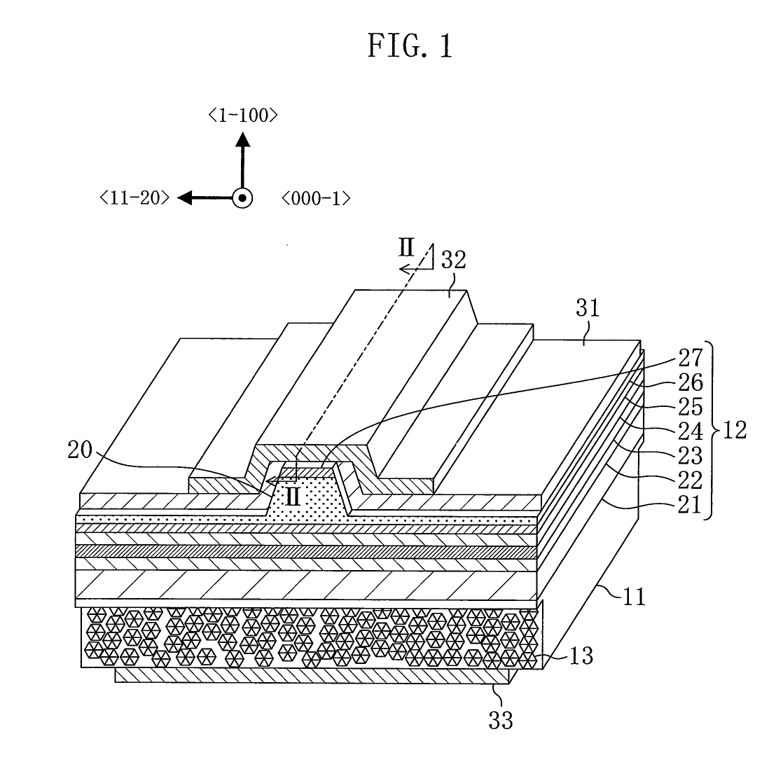

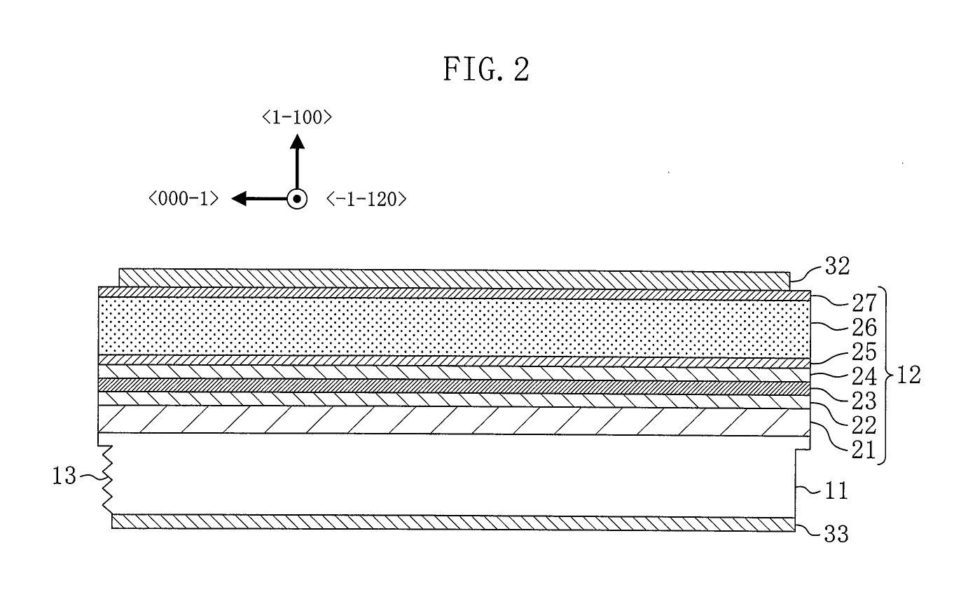

An embodiment of the present disclosure will be described with reference to the accompanying drawings. FIGS. 1 and 2 illustrate a semiconductor laser device according to the embodiment. FIG. 1 shows the entire three-dimensional structure, and FIG. 2 shows a cross-sectional structure taken along the line II-II of FIG. 1.

As shown in FIGS. 1 and 2, the semiconductor laser device of this embodiment is an edge-emitting semiconductor laser device, and includes a substrate 11 and a semiconductor multilayer structure 12. The substrate 11 has a (1-100) oriented principal surface, and is made of n-type GaN. The semiconductor multilayer structure 12 is formed on the substrate 11, and has a stripe-shaped optical waveguide. The semiconductor multilayer structure 12 includes an n-type clad layer 21, an n-type optical guide layer 22, an active layer 23, a p-type optical guide layer 24, a carrier overflow suppression layer (an OFS layer) 25, a p-type clad layer 26, and a p-type contact layer 27 sequentially formed in that order. The p-type clad layer 26 is formed so as to have the shape of a ridge stripe, and is covered with a dielectric layer 31 except for the top of the ridge stripe portion 20 where the p-type contact layer 27 is formed. On the dielectric layer 31, a p-side electrode 32 is formed so as to cover the ridge stripe portion 20. An n-side electrode 33 is formed on the side (the backside) of the substrate 11 located away from the semiconductor multilayer structure 12.

On the substrate 11 exposed in a light emitting facet, which is a facet that emits laser light, pyramidal protrusions 13 are formed. As will be discussed later, the pyramidal protrusions 13 are formed of (1-102) oriented surfaces (r planes) exposed by etching of the substrate 11 made of the nitride semiconductor.

The semiconductor laser device of this embodiment has the pyramidal protrusions 13, which scatter return laser light entering the light emitting facet of the semiconductor laser device. This significantly reduces noise occurring due to re-formation of a spot on the optical disc by the return laser light. Furthermore, the pyramidal protrusions 13, which are r planes of the substrate 11, have the same level of resistance to laser light as the other part of the substrate 11. Therefore, unlike in the case in which a light absorption layer or the like is formed by using a resist or other material, laser-light-caused degradation presents no problem. Moreover, the processing is easy because the r planes of the substrate 11 are just exposed by etching.

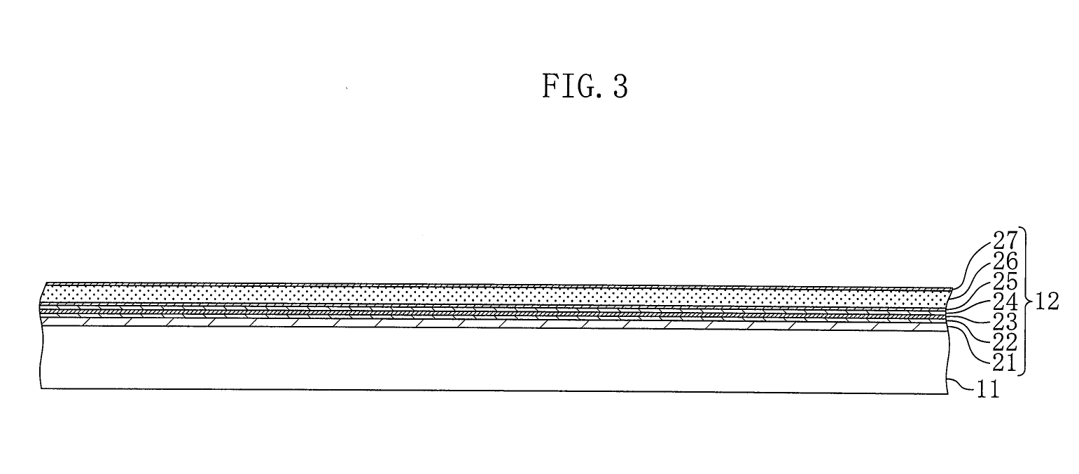

Next, a method for fabricating the semiconductor laser device according to the embodiment of the present disclosure will be described. First, as shown in FIG. 3, the n-type clad layer 21, the n-type optical guide layer 22, the active layer 23, the p-type optical guide layer 24, the OFS layer 25, the p-type clad layer 26, and the p-type contact layer 27 are formed in sequence on the (1-100) oriented principal surface of the n-type GaN substrate 11 by metalorganic chemical vapor deposition (MOCVD) or other method, thereby forming the semiconductor multilayer structure 12.

The n-type clad layer 21 may be made of 2-μm-thick n-type Al_{0.03}Ga_{0.97}N. The n-type optical guide layer 22 may be made of 0.1-μm-thick n-type GaN. The active layer 23 may have a multi-quantum well (MQW) structure formed by stacking, for example, a barrier layer made of In_{0.02}Ga_{0.98}N and a quantum well layer made of In_{0.06}Ga_{0.94}N three times. The p-type optical guide layer 24 may be made of 0.1-μm-thick p-type GaN. The OFS layer 25 may be made of 10-nm-thick Al_{0.20}Ga_{0.80}N. The p-type clad layer 26 may be a 0.48-μm-thick strained superlattice obtained by repeating formation of a p-type Al_{0.16}Ga_{0.84}N layer and a GaN layer, each having a thickness of 1.5 nm, 160 times. The p-type contact layer 27 may be made of 0.05-μm-thick p-type GaN.

In forming the semiconductor multilayer structure 12 by MOCVD, for example, trimethylgallium (TMG), trimethylindium (TMI), and trimethylaluminum (TMA) may be respectively used as a Ga source material, an In source material, and an Al source material, and ammonia (NH₃) may be used as an N source material. Furthermore, a silane (SiH₄) gas may be used to introduce Si as an n-type impurity, and bis(cyclopentadienyl) magnesium (Cp₂Mg) may be used to introduce Mg as a p-type impurity.

To form the semiconductor multilayer structure 12, molecular beam epitaxial (MBE), chemical beam epitaxial (CBE), or other method by which group III-V nitride semiconductor layers can be grown may also be employed instead of MOCVD.

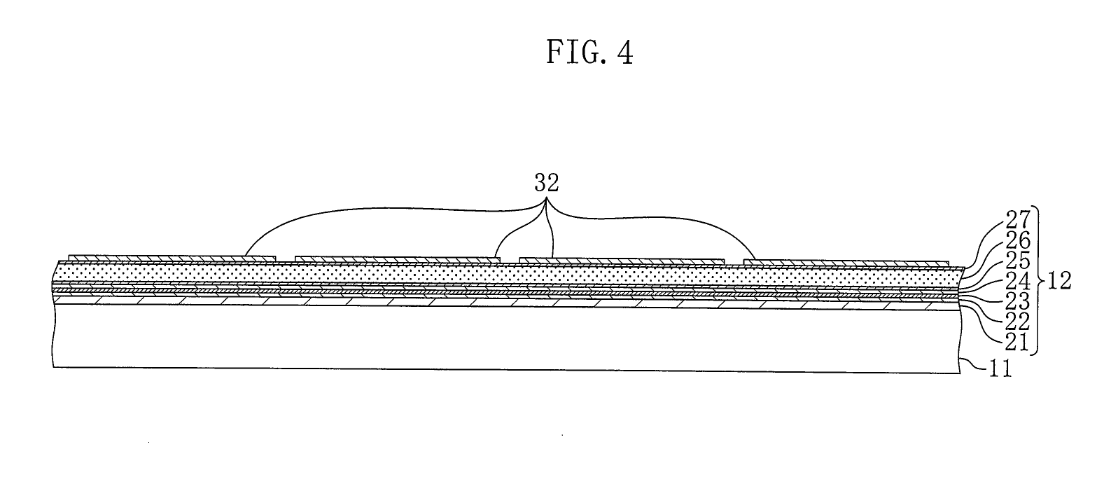

Next, as shown in FIG. 4, p-side electrodes 32 are formed. First, a first mask film (not shown) made of 0.3-μm-thick SiO₂ is grown on the p-type contact layer 27 by thermal CVD, for example. The first mask film is patterned into 1.5-μm-wide stripes in parallel with the c-axis direction by lithography and etching.

Subsequently, with the first mask film being used, the upper part of the semiconductor multilayer structure 12 is etched to a depth of 0.35 μm by inductively coupled plasma (ICP) etching, so that ridge stripe portions are formed out of the p-type contact layer 27 and the upper part of the p-type clad layer 26. Thereafter, the first mask film is removed using a hydrofluoric aid, and a dielectric layer (not shown) having a thickness of 200 nm and made of SiO₂ is formed over the exposed part of the p-type clad layer 26 as well as over the ridge stripe portions 20 by thermal CVD again. This dielectric layer serves as the dielectric layer 31 shown in FIG. 1.

Next, a resist pattern (not shown) that has 1.3-μm-wide openings extending along the ridge stripe portions and exposing the upper surfaces of these ridge stripe portions is formed by lithography. Subsequently, with the resist pattern used as a mask, the dielectric layer is etched by reactive ion etching (RIE) using, for example, a trifluoromethane (CHF₃) gas, thereby forming openings, which expose the p-type contact layers 27, in the upper surfaces of the ridge stripe portions.

Then, a metal multilayer film, composed of 40-nm-thick palladium (Pd) and 35-nm-thick platinum (Pt), is formed at least on the p-type contact layers 27 exposed through the openings by electron beam (EB) evaporation or other method. Thereafter, a lift-off method for removing the resist pattern is performed to remove the part of the metal multilayer film formed other than on the ridge stripe portions, thereby forming p-side electrodes 32 such as shown in FIG. 4.

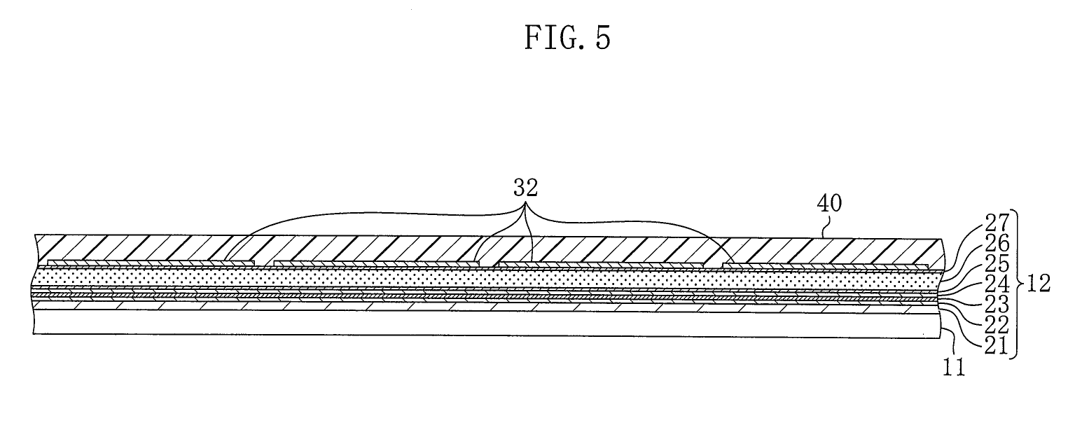

Next, as shown in FIG. 5, an etching protective film 40 made of a resin material, such as a resist or a wax, is formed over the substrate 11 so as to cover the semiconductor multilayer structure 12 having the p-side electrodes 32 formed thereon. Then, the backside of the substrate 11 is polished using diamond slurry until the substrate 11 has a thickness of about 100 μm.

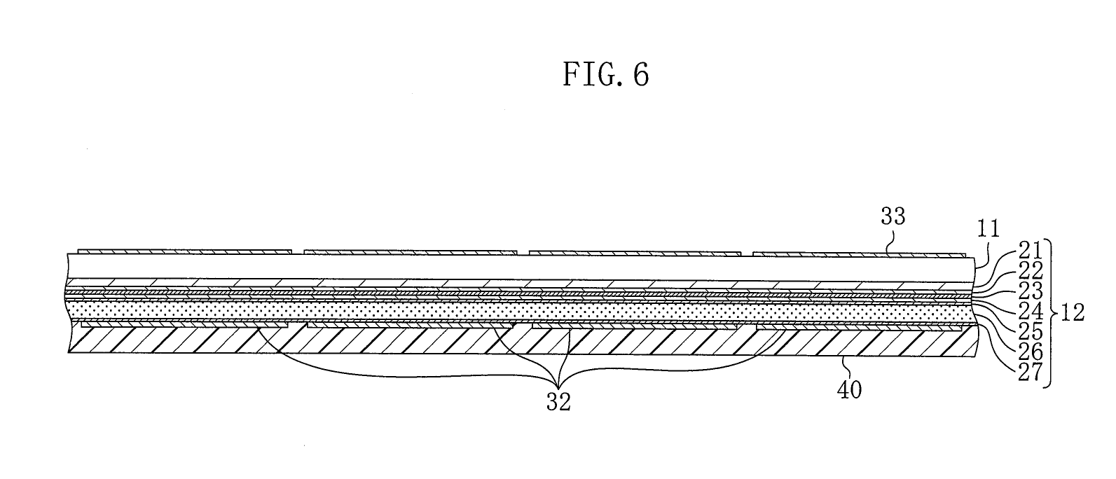

Subsequently, as shown in FIG. 6, n-side electrodes 33 are formed on the backside of the substrate 11. The n-side electrodes 33 are formed as follows. First, a resist pattern (not shown) is formed on the backside of the substrate 11 by lithography. Then, a metal multilayer film, made of 5-nm-thick Ti, 10-nm-thick platinum, and 1000-nm-thick Au, is evaporated by EB evaporation or other method. Next, a lift-off method for removing the resist pattern is performed to remove unnecessary part of the metal multilayer film, thereby forming the n-side electrodes 33.

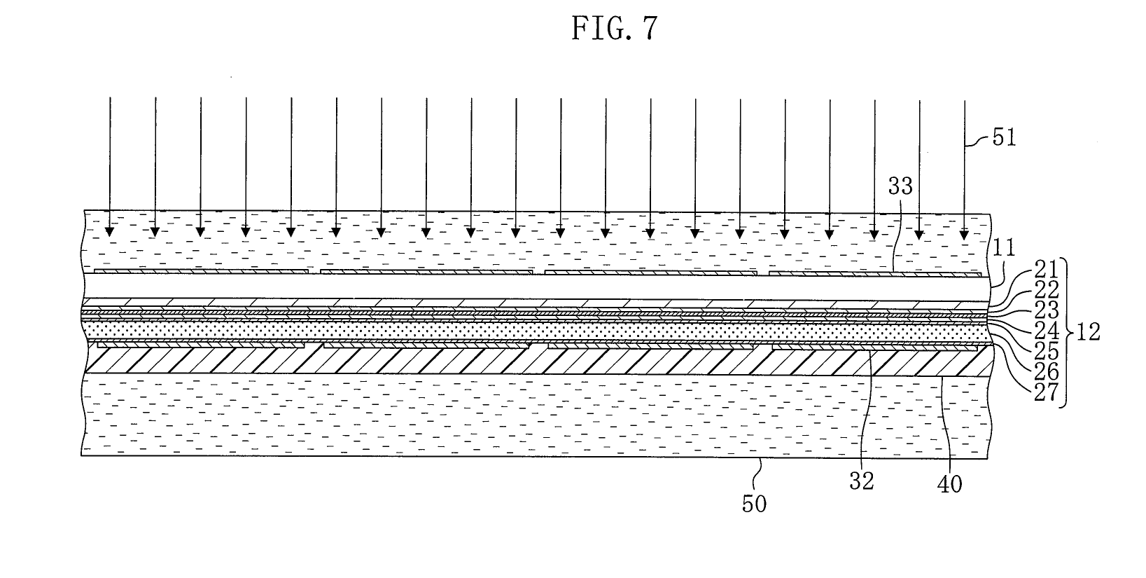

Then, as shown in FIG. 7, with each n-side electrode 33 used as a mask, wet etching is performed. This wet etching may be performed with an alkaline solution 50 used as an etchant, and with the substrate 11 irradiated with UV (ultraviolet) light. The substrate 11 absorbs the UV light, thereby generating electron-hole pairs. The electrons of the generated electron-hole pairs are released from the substrate 11 into the alkaline solution 50 through the n-side electrodes 33. That is, the n-side electrodes 33 function as cathode electrodes. The holes of the generated electron-hole pairs, together with the OH⁻ group in the alkaline solution 50, contribute to the etching of the substrate 11. In this embodiment, a potassium hydroxide (KOH) solution is used as the alkaline solution 50. However, the alkaline solution 50 is not limited to KOH, and NaOH or the like may also be used. Furthermore, the irradiation light is not limited to UV light, but may be any light having such a wavelength that causes the nitride semiconductor crystals forming the substrate 11 to absorb the light.

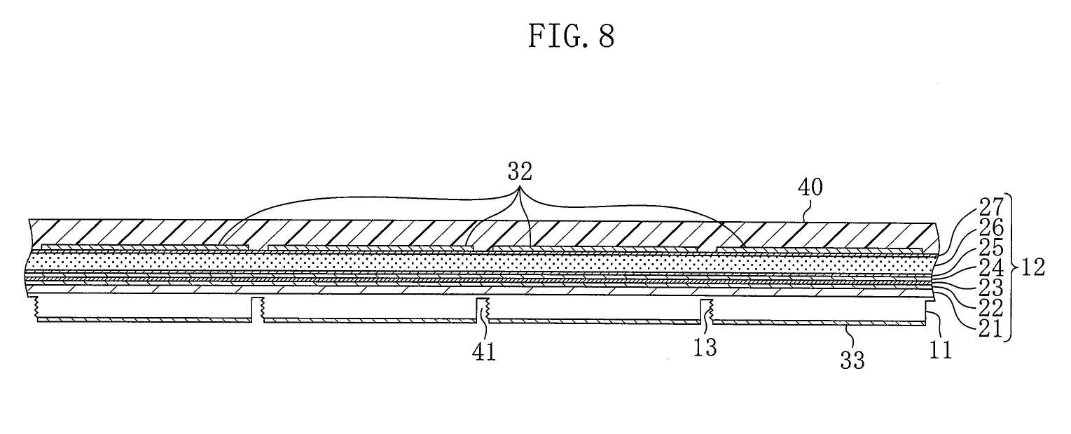

As shown in FIG. 8, as a result of the wet etching using the alkaline solution 50 and the UV light irradiation, recesses 41 having (000-1) oriented inner wall surfaces are formed in the substrate 11, and pyramidal protrusions 13 each in the shape of a hexagonal pyramid are formed on the (000-1) oriented +c planes of the inner wall surfaces of the recesses 41.

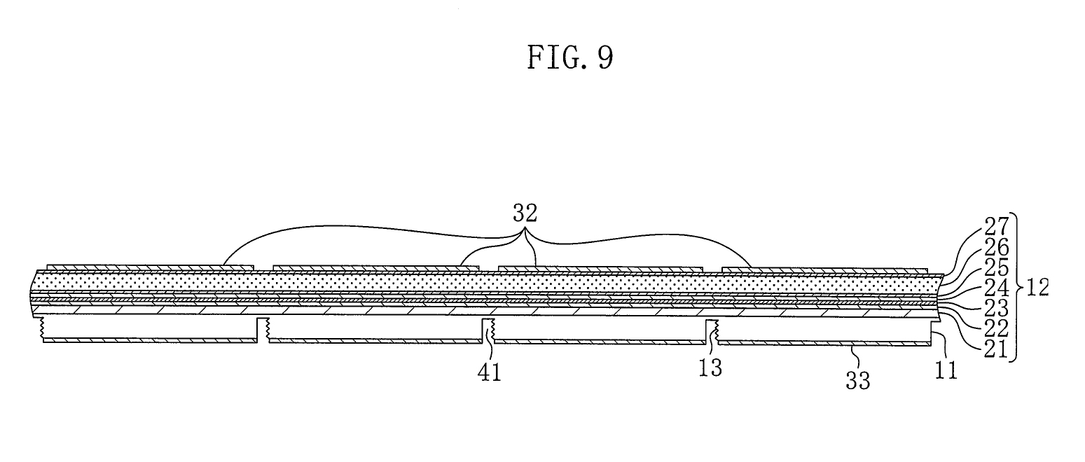

Next, the etching protective film 40 is removed as shown in FIG. 9. Thereafter, with the recesses 41 being used, the substrate 11 as a wafer is subjected to primary cleavage so as to have a length of 600 μm in the c-axis direction. After the first cleavage, the substrate 11 undergoes secondary cleavage so as to have a length of 200 μm in the α-axis direction. This results in the formation of semiconductor laser devices each having the pyramidal protrusions 13 on the substrate 11 exposed in the light emitting facet. The recesses 41 may be formed as continuous grooves extending in the direction of the primary cleavage, or may be formed intermittently only in the locations where the pyramidal protrusions 13 are needed.

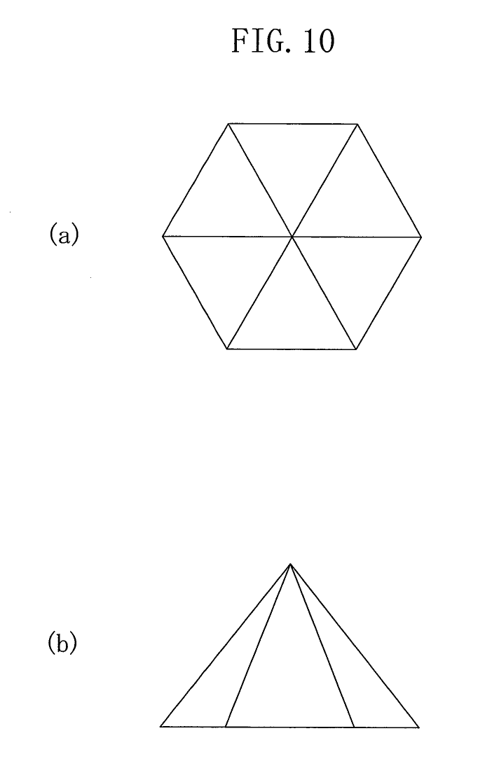

The pyramidal protrusions 13 are formed of the (1-102) oriented r planes exposed by etching. Thus, ideally, the pyramidal protrusions 13 each have the shape of a hexagonal pyramid formed by combinations of r planes as shown in FIGS. 10(a) and 10(b). FIG. 10(a) is a plan view, and FIG. 10(b) is a side view. The pyramidal protrusions 13 formed by etching are of a size in which the length of their diagonals shown in the plan view of FIG. 10(a) is from about several tens of nm to about several μm. The pyramidal protrusions 13 are typically formed with diagonals having a length of from about 0.5 μm to about 1.0 μm. These pyramidal protrusions 13 are sufficiently capable of scattering blue-violet laser light having a wavelength of about 405 nm. Furthermore, since the pyramidal protrusions having diagonals of about several tens of nm are sufficiently smaller than the wavelength, 405 nm, of blue-violet laser light, the effective refractive index of their surfaces is lowered, allowing the pyramidal protrusions to function as an antireflection structure as well.

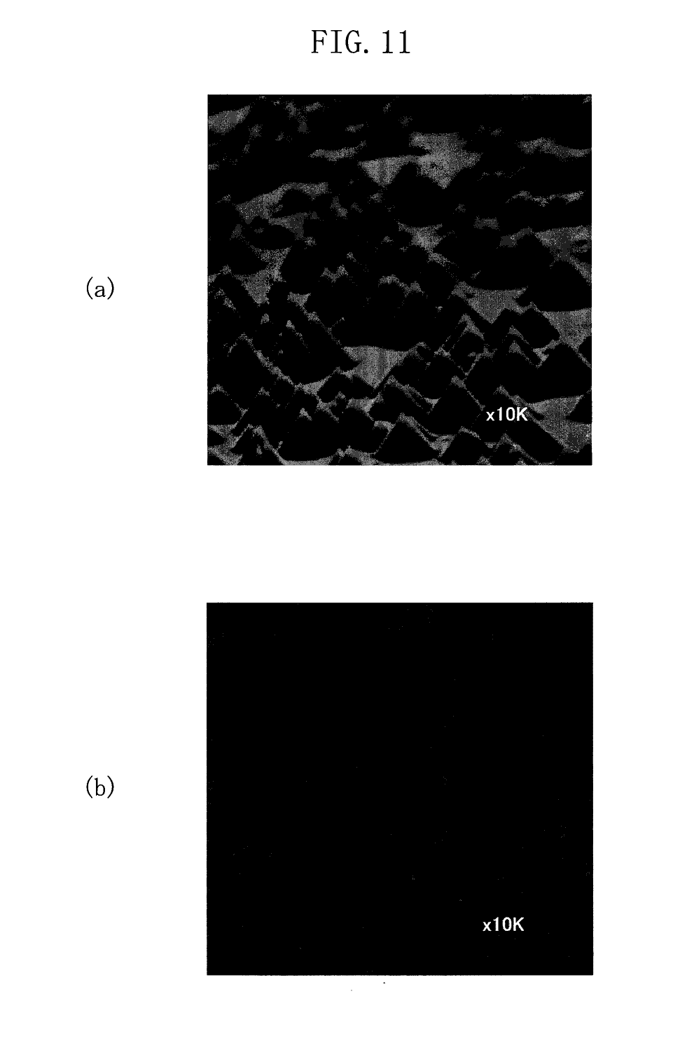

FIGS. 11(a) and 11(b) show electron micrographs of actually obtained pyramidal protrusions 13. As shown in FIG. 11(a), the pyramidal protrusions 13 each in the shape of a hexagonal pyramid are obtained. Due to etching conditions and other factors, however, distorted pyramidal protrusions 13 such as shown in FIG. 11(b) may result. Nevertheless, even if the pyramidal protrusions 13 are not completely shaped like a hexagonal pyramid, the effect of scattering return laser light is not affected.

In this embodiment, the pyramidal protrusions 13 are formed only on a facet of the substrate 11. However, the pyramidal protrusions 13 may also be formed on any part of a facet of the semiconductor multilayer structure 12 so long as the part is located under the active layer 23. In that case, in the etching process shown in FIG. 7, for example, not only the substrate 11 but also such a part of the semiconductor multilayer structure 12 may be etched.

Furthermore, in the above-described example semiconductor laser device, the pyramidal protrusions 13 are formed on the facet across the width of the cavity. However, if a location where return laser light reflection is particularly like to occur is specified, the pyramidal protrusions 13 may be formed only in that location. For example, it is generally said that the location where return laser light from an optical system reenters the semiconductor laser device is approximately 50 μm away from the laser light emitting location. Therefore, the pyramidal protrusions 13 may be formed in such a location.

Also, in this embodiment, the semiconductor laser device having a ridge-stripe optical waveguide has been described. However, the same effects are also achievable in an embedded semiconductor laser device or in a semiconductor laser device of electrode stripe structure, for example.

Moreover, the substrate 11 is not limited to GaN, but may be made of a hexagonal nitride semiconductor including other group III-V nitride semiconductor, such as AlGaN. In that case, it is also possible to form pyramidal protrusions in the same manner.

### INDUSTRIAL APPLICABILITY

The semiconductor laser devices according to the present disclosure, which easily realize semiconductor laser devices capable of preventing return light reflection, are particularly applicable to semiconductor laser devices and the like used as light sources in optical disk devices and the like.

1. A semiconductor laser device, which is an edge-emitting semiconductor laser device using a nitride semiconductor, the device comprising:
a substrate made of a hexagonal nitride semiconductor and having a (1-100) oriented principal surface;
a semiconductor multilayer structure formed on the substrate and having a stripe-shaped optical waveguide; and
a plurality of pyramidal protrusions formed at least on a part of a region of a light emitting facet, the region being an area of the substrate exposed in the light emitting facet,
wherein the light emitting facet has a (000-1) plane orientation.

2. The semiconductor laser device of claim 1, wherein the pyramidal protrusions are each shaped like a hexagonal pyramid, and are formed of (1-102) oriented surfaces.

3. The semiconductor laser device of claim 1, wherein the semiconductor multilayer structure includes an n-type clad layer, an active layer, and a p-type clad layer sequentially stacked in this order; and
the pyramidal protrusions are also formed at least on a part of a region of the light emitting facet, the region being an area of the semiconductor multilayer structure exposed in the light emitting facet, the part being located under the active layer.

4. A method for fabricating a semiconductor laser device, comprising the steps of:
(a) forming a semiconductor multilayer structure on a substrate having a (1-100) oriented principal surface, the semiconductor multilayer structure having a stripe-shaped optical waveguide; and
(b) forming a recess having a (000-1) oriented inner wall surface by etching a side of the substrate located away from a side thereof where the semiconductor multilayer structure is formed, and forming pyramidal protrusions of (1-102) oriented surfaces on the inner wall surface.

5. The semiconductor laser device fabrication method of claim 4, wherein the etching is wet etching.

6. The semiconductor laser device fabrication method of claim 5, wherein the wet etching is performed with an alkaline solution used as an etchant and with light applied, the light having such a wavelength that causes crystals of the nitride semiconductor to absorb the light.

7. The semiconductor laser device fabrication method of claim 6, wherein the alkaline solution is a potassium hydroxide solution.

8. The semiconductor laser device fabrication method of claim 4, further comprising the step (c) of cleaving the semiconductor multilayer structure, thereby forming a cavity facet, after the step (b) has been performed,
wherein the recess functions as a guide groove in the cleavage.

9. The semiconductor laser device fabrication method of claim 4, further comprising the step (d) of forming an n-side electrode on the side of the substrate located away from the semiconductor multilayer structure, before the step (b) is performed,
wherein in the step (b), the etching is performed with the n-side electrode used as a mask.
